(19) United States
(12) Patent Application Publication
(10) Pub. No.: US 2022/0199584 A1
(43) Pub. Date: Jun. 23, 2022

(54) FOLDABLE DOLL WITH PROJECTION FUNCTION

(71) Applicant: Shenzhen Sunrise Technology Co., Ltd., Shenzhen (CN)

(72) Inventor: Min JI, Shenzhen (CN)

(21) Appl. No.: 17/688,801

(22) Filed: Mar. 7, 2022

Related U.S. Application Data
(63) Continuation-in-part of application No. 17/406,745, filed on Aug. 19, 2021.
Application No. 17/406,745 is a continuation of application No. 16/683,130, filed on Nov. 13, 2019, now abandoned.
(60) Provisional application No. 62/760,485, filed on Nov. 13, 2018.

(30) Foreign Application Priority Data
Jun. 10, 2021 (CN) 202121303042.4

(51) Int. Cl. H01L 25/065; H01L 23/00; G06N 10/00

(52) U.S. Cl. CPC H01L 25/0657; H01L 24/16; H01L 24/13; H01L 27/18; H01L 2224/13644; H01L 2224/13109; G06N 10/00

(57) ABSTRACT

A foldable doll includes: a doll body which is a hollow structure; a projection lamp disposed in the doll body; a power connector electrically connected to the projection lamp; a supporting assembly for supporting the doll body; a plurality of supporting rings sewn on the doll body; a blower connected to the doll body and electrically connected to the power connector. The projection lamp includes a lamp cover, a motor, and a projection unit. The motor includes a rotation shaft, and the projection unit is fixedly disposed on the rotation shaft and configured to emit and project light on the lamp cover. The blower is electrically connected to the power connector. In an unfolded state, the doll body is propped up by the supporting assembly, and in a folded state, the supporting assembly is detached from the doll body, and the doll body automatically collapses by gravity.

### CROSS-REFERENCE TO RELATED APPLICATIONS

This application is a continuation-in-part of U.S. application Ser. No. 17/406,745 filed Aug. 19, 2021, now pending, and claims the benefit of Chinese Patent Application No. 202121303042.4 filed Jun. 10, 2021. The contents of all of the aforementioned applications, including any intervening amendments thereto, are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, Mass. 02142.

### BACKGROUND

The disclosure relates to a foldable doll with projection function.

Since ancient times, decorative dolls have been used in magic and religious rituals, and for entertainment and enjoyment. Dolls have also traditionally been toys for children.

Conventional standing dolls are stuffed with support linings, such as cotton, to give the dolls stability when standing. The support linings can be removed for easy storage of the dolls. This, however, brings about inconvenience.

### SUMMARY

The disclosure provides a foldable doll with projection function. To fold the doll, the doll body automatically collapses and folds by gravity for easy storage; when in working, the doll body is propped up by the supporting assembly to project colorful lights.

To achieve the above technical proposal, the disclosure provides a foldable doll comprising: a doll body which is a hollow structure; a projection lamp disposed in the doll body; a power connector electrically connected to the projection lamp; a supporting assembly for supporting the doll body; a plurality of supporting rings sewn on the doll body; a blower connected to the doll body and electrically connected to the power connector. The doll body comprises a waterproof, inflatable, and light-permeable fabric; the projection lamp comprises a lamp cover, a motor, and a projection unit; the motor comprises a rotation shaft, and the projection unit is fixedly disposed on the rotation shaft and configured to emit and project light on the lamp cover; in an unfolded state, the doll body is propped up by the supporting assembly, and in a folded state, the supporting assembly is detached from the doll body, and the doll body automatically collapses by gravity.

In a class of this embodiment, the doll body comprises a head and a bottom opening; the plurality of supporting rings is disposed in parallel to each other in the doll body from the head to the bottom opening; the supporting assembly comprises a straight tube and a base; the straight tube is disposed through the head and the bottom opening, and is fixed on the base; the straight tube and the plurality of supporting rings cooperate to support the doll body to form a three-dimensional hollow doll.

In a class of this embodiment, the plurality of supporting rings comprises a top supporting ring; the top supporting ring is disposed inside the head and is arranged above others of the plurality of supporting rings; the top supporting ring comprises a plurality of spokes; the plurality of spokes is connected to each other at a center of the top supporting ring; one end of the straight tube is detachably connected to the center of the top supporting ring.

In a class of this embodiment, the head of the doll body is provided with a first LED lamp electrically connected to the power connector.

In a class of this embodiment, the doll body is provided with a gift box, and the gift box is provided with a second LED lamp electrically connected to the power connector.

In a class of this embodiment, the bottom opening of the doll body is sealed by a zipper and a zipper tape in cooperation.

In a class of this embodiment, the blower, the first LED lamp, and the second LED lamp are connected to the doll body by a cable tie.

In a class of this embodiment, a wire of the power connector extends into one or more connecting terminals, and a power cord of the blower, a power cord of the LED lamp, and a power cord of the projection lamp are connected to the wire of the power connector through the one or more connecting terminals.

In a class of this embodiment, the projection lamp is disposed on a lower end of the doll body by a cable tie.

The following advantageous are associated with the foldable doll with projection function of the disclosure:

(1) when then supporting assembly is removed, the doll body automatically collapses and folds, which is easy to store and use;

(2) when in working, the doll body is propped up by the supporting assembly to project colorful lights;

(3) the straight pipe and supporting rings are used to prop the doll body up to facilitate folding; and

(4) the blower is provided and cooperates with the supporting assembly, which can automatically blow up the doll body and when the blower and the supporting assembly are removed, the doll automatically collapses, which is easy to use.

### BRIEF DESCRIPTION OF THE DRAWINGS

FIG. 1 is a front view of a foldable doll with projection function according to one embodiment of the disclosure;

FIG. 2 is a right view of the foldable doll with projection function shown in FIG. 1;

FIG. 3 is a top view of the foldable doll with projection function shown in FIG. 1;

FIG. 4 is a schematic diagram of the foldable doll with projection function shown in FIG. 1 in a folded state;

FIG. 5 is a perspective schematic diagram of the foldable doll with projection function shown in FIG. 1;

FIG. 6 is a front view of a foldable doll with projection function according to another embodiment of the disclosure;

FIG. 7 is a right view of a foldable doll with projection function shown in FIG. 6;

FIG. 8 is a top view of a foldable doll with projection function shown in FIG. 6;

FIG. 9 is a perspective schematic diagram of a foldable doll with projection function shown in FIG. 6; and

FIG. 10 is an exploded view of a projection lamp of a foldable doll with projection function in FIG. 6.

In the drawings, the following reference numbers are used: 1. Doll body; 11. Supporting ring; 111. Top supporting ring; 112. Spoke; 2. Projection lamp; 22. Lamp cover; 23. Projection unit; 26. Motor; 3. Blower; 4. Power connector; 5. LED lamp; 6. Gift box; 7. Zipper; 8. Zipper tape; 9. Cable tie; 10. Connecting terminal; 20. Supporting assembly; 201. Straight tube; 30. Needle and thread.

### DETAILED DESCRIPTION

To further illustrate, embodiments detailing a foldable doll with projection function are described below. It should be noted that the following embodiments are intended to describe and not to limit the disclosure.

The disclosure provides a foldable doll comprising a doll body 1 which is a hollow structure; a projection lamp 2 disposed in the doll body 1; a power connector 4 electrically connected to the projection lamp 2; a supporting assembly 20 for supporting the doll body 1; a plurality of supporting rings 11 sewn on the doll body; a blower 3 connected to the doll body 1 and electrically connected to the power connector 4.

The doll body 1 comprises a waterproof, inflatable, and light-permeable fabric. For example, the fabric comprises a polyester fiber material with a waterproof coating. The projection lamp 2 comprises a lamp cover 22, a motor 26, and a projection unit 23; the motor comprises a rotation shaft, and the projection unit is fixedly disposed on the rotation shaft and configured to emit and project light on the lamp cover; the blower 3 is electrically connected to the power connector 4; in an unfolded state, the doll body 1 is propped up by the supporting assembly 20, and in a folded state, the supporting assembly 20 is detached from the doll body, and the doll body 1 automatically collapses by gravity.

### Example 1

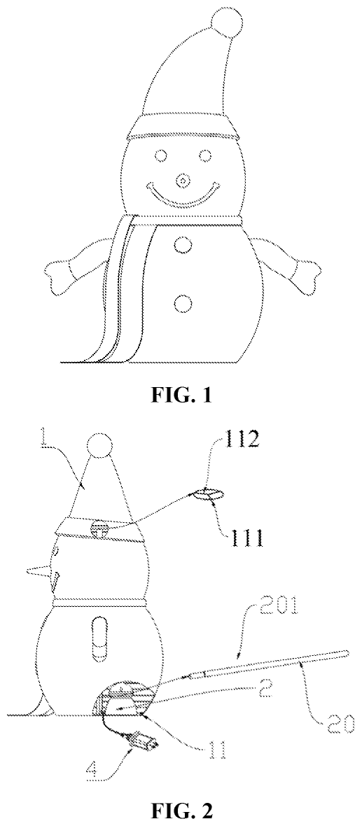

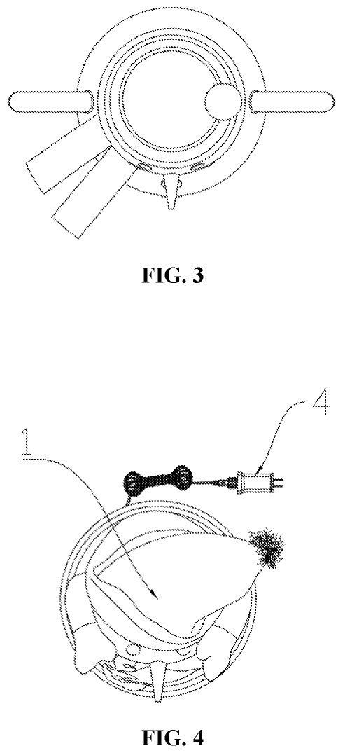

As shown in FIGS. 1-5, the doll body 1 comprises a head and a bottom opening; the plurality of supporting rings 11 is disposed in parallel to each other in the doll body from the head to the bottom opening; the supporting assembly 20 comprises a straight tube 201 and a base; the straight tube is disposed through the head and the bottom opening, and is fixed on the base; the plurality of supporting rings 11 comprises a top supporting ring 111; the top supporting ring 111 is disposed inside the head and is arranged above others of the plurality of supporting rings 11; the top supporting ring 111 comprises a plurality of spokes 112; the plurality of spokes 112 is connected to each other at a center of the top supporting ring 111; one end of the straight tube 201 is connected to the center of the top supporting ring 111; the straight tube and the plurality of supporting rings 11 cooperate to support the doll body to form a three-dimensional hollow doll.

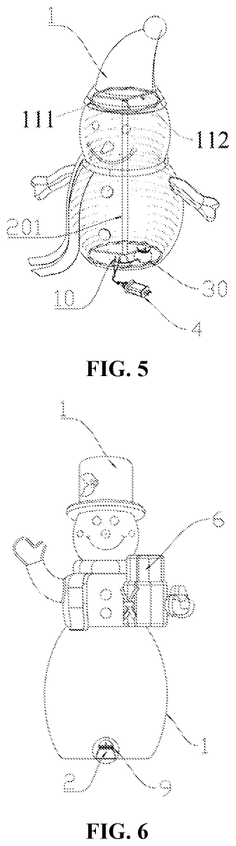

Specifically, as shown in FIG. 5, the supporting rings 11 are sewn with the doll body 1 by a needle and thread 30.

The foldable doll with projection function in the example is in a folded state under nonuse condition, which is easy to store. To display the doll, a user only needs to lift the doll's head, and the supporting rings 11 will prop the entire doll's body up; optionally, the top supporting rings 111 can also be connected to the top end of the straight tube 201 to push the top of the straight tube 201 against the inner top surface of the doll's head, so the whole doll body 1 is propped up, and the straight tube 201 is seated on the base to achieve stable propping.

When the doll body 1 is in an unfolded state, powering the power connector 4, the projection unit emits and projects light on the doll body; if the doll body is hollowed out, the light and shadow effects can also be projected on the ceiling to achieve beautiful visual effects.

As shown in FIG. 4, the foldable doll with projection function in the example naturally collapses in the folded state, which occupies a small space, is easy to store, and brings convenience to the user.

### Example 2

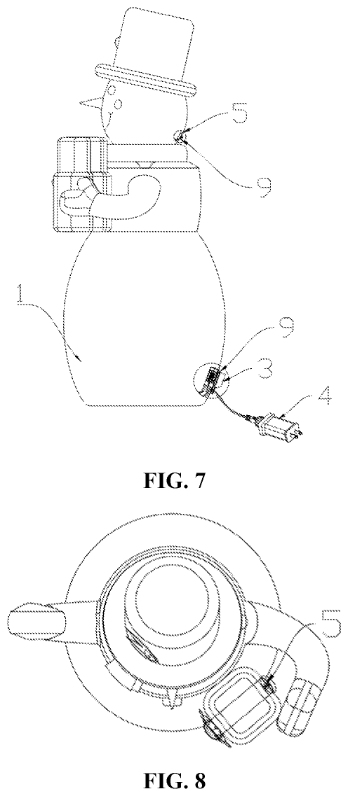

As shown in FIGS. 6-9, a foldable doll with projection function in the example comprises a hollow doll body 1, a projection lamp 2 disposed in the doll body 1, a power connector 4 that is electrically connected to the projection lamp 2, and a supporting assembly 20 for supporting the doll body 1; under normal conditions, the doll body 1 automatically collapses by gravity; when in working, the doll body 1 is propped up by the supporting assembly 20.

The main difference between the foldable doll with projection function in the example and the foldable doll with projection function in Example 1 is: the doll body 1 is an inflatable doll. As shown in FIG. 7, the supporting assembly 20 comprises a blower 3 connected to the doll body 1, and the blower 3 is electrically connected to the power connector 4. Therefore, when power is supplied to the power connector 4, the blower 3 automatically inflates the doll body 1 to prop it up.

To realize the strong enough light inside the inflatable doll, as shown in FIG. 7, the head of the doll body 1 is provided with a first LED lamp 5 electrically connected to the power connector 4. Further, the doll body 1 is provided with a gift box 6, and the gift box 6 is provided with a second LED lamp electrically connected to the power connector 4.

To facilitate the installation of the projection lamp 2 on the bottom of the doll body 1, as shown in FIG. 9, the bottom opening of the doll body 1 is sealed by a zipper 7 and a zipper tape 8 in cooperation, so that the installation of the projection lamp 2 and the installation of other electronic components can be easily realized.

In a specific application, as shown in FIG. 6 and FIG. 7, the blower 3 and the LED lamp 5 are connected to the doll body 1 by a cable tie 9 to realize a quick connection.

With further reference to FIG. 7, as for the foldable doll with projection function in Example 2, the wire of the power connector 4 extends into one or more connecting terminals, and a power cord of the blower 3, a power cord of the LED lamp 5, and a power cord of the projection lamp 2 are connected to the wire of the power connector 4 through the one or more connecting terminals 10, which facilitates wiring and installation.

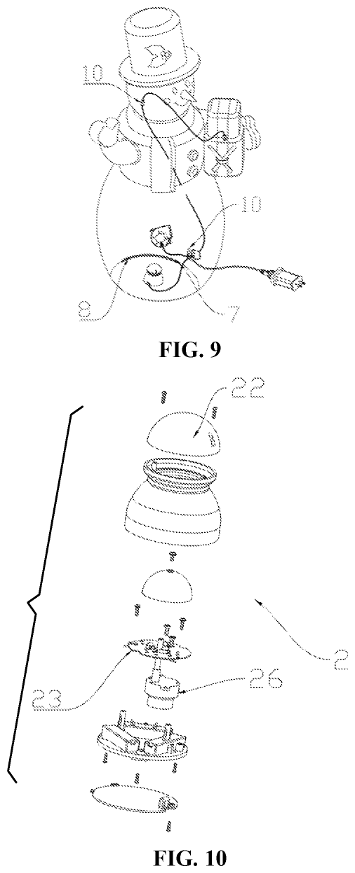

In the example of the disclosure, as shown in FIG. 10, the projection lamp 2 comprises a lamp cover 22, a motor 26, and a projection unit 23; the motor comprises a rotation shaft, and the projection unit is fixedly disposed on the rotation shaft and configured to emit and project light on the lamp cover; when in working, the motor 26 drives the rotation shaft and the projection unit 23 to rotate, and the projection unit 23 projects colorful lights.

Further, the projection lamp 2 is disposed on a lower end of the doll body 1 by the cable tie 9 to ensure the firmness of the connection between the projection lamp 2 and the doll body 1.

It will be obvious to those skilled in the art that changes and modifications may be made, and therefore, the aim in the appended claims is to cover all such changes and modifications.

The invention claimed is:

1. A device, comprising:
a doll body which is a hollow structure;
a projection lamp disposed in the doll body;
a power connector electrically connected to the projection lamp;
a supporting assembly for supporting the doll body;
a plurality of supporting rings sewn on the doll body;
a blower connected to the doll body and electrically connected to the power connector;
wherein:
the doll body comprises a waterproof, inflatable, and light-permeable fabric;
the projection lamp comprises a lamp cover, a motor, and a projection unit; the motor comprises a rotation shaft, and the projection unit is fixedly disposed on the rotation shaft and configured to emit and project light on the lamp cover; and
in an unfolded state, the doll body is propped up by the supporting assembly, and in a folded state, the supporting assembly is detached from the doll body, and the doll body automatically collapses by gravity.

2. The device of claim 1, wherein the doll body comprises a head and a bottom opening; the plurality of supporting rings is disposed in parallel to each other in the doll body from the head to the bottom opening; the supporting assembly comprises a straight tube and a base; the straight tube is disposed through the head and the bottom opening, and is fixed on the base; the straight tube and the plurality of supporting rings cooperate to support the doll body to form a three-dimensional hollow doll.

3. The device of claim 2, wherein the head of the doll body is provided with a first LED lamp electrically connected to the power connector.

4. The device of claim 3, wherein the doll body is provided with a gift box, and the gift box is provided with a second LED lamp electrically connected to the power connector.

5. The device of claim 4, wherein the bottom opening of the doll body is sealed by a zipper and a zipper tape in cooperation.

6. The device of claim 5, wherein the blower, the first LED lamp, and the second LED lamp are connected to the doll body by a cable tie.

7. The device of claim 6, wherein a wire of the power connector extends into one or more connecting terminals, and a power cord of the blower, a power cord of the LED lamp, and a power cord of the projection lamp are connected to the wire of the power connector through the one or more connecting terminals.

8. The device of claim 1, wherein the projection lamp is disposed on a lower end of the doll body by a cable tie.

9. The device of claim 2, wherein the plurality of supporting rings comprises a top supporting ring; the top supporting ring is disposed inside the head and is arranged above others of the plurality of supporting rings; the top supporting ring comprises a plurality of spokes; the plurality of spokes is connected to each other at a center of the top supporting ring; and one end of the straight tube is detachably connected to the center of the top supporting ring.
